(19) United States
(12) Patent Application Publication
(10) Pub. No.: US 2004/0157465 A1
(43) Pub. Date: Aug. 12, 2004

(54) Method for manufacturing an electronic device including removing a resist mask used in etching a substrate by ashing

(75) Inventor: Kenji Kawai, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/449,128

(22) Filed: Jun. 2, 2003

(30) Foreign Application Priority Data
Feb. 12, 2003 (JP) 2003-034028

(51) Int. Cl. H01L 21/302

(52) U.S. Cl. 438/736

(57) ABSTRACT

A method for manufacturing an electronic device, in which a film of low dielectric constant is subjected to etching while a resist pattern formed on a substrate—on which the film of low dielectric constant is formed—is taken as a mask. Subsequently, the resist pattern is removed by ashing through use of ashing gas. After the ashing operation, an alteration layer formed on the film of low dielectric constant is removed. Alternatively, before ashing operation, a thin film for inhibiting penetration of oxygen is formed on the surface or side surfaces of the film of low dielectric constant. Further alternatively, gas which inhibits oxidization of the film of low dielectric constant is used as the ashing gas.

### BACKGROUND OF THE INVENTION

1. Field of the Invention

The invention relates to a method for manufacturing an electronic device. More particularly, the invention relates to a method for manufacturing an electronic device including an ashing step of removing the resist mask used in a step of etching a substrate or like.

2. Background Art

When a hole pattern or a trench pattern is formed in a dielectric film having a low dielectric constant (hereinafter called a “low-k film”), first the dielectric film is formed on a substrate, and then an anti-reflection coating is formed on the dielectric film. Subsequently, after a resist film has been formed on the anti-reflection coating, a desired resist pattern is formed. The substrate is subjected to etching while the resist pattern is taken as a mask, thereby forming a hole pattern or a trench pattern in the dielectric film or the like. Subsequently, the resist pattern is removed.

When an F-based gas or a gas mixture containing at least a fluorine gas and an O-based gas is used at the time of formation of the hole pattern or the trench pattern, a fluorocarbon-based polymer film is formed on a side wall of the pattern formed in the dielectric film. If the fluorocarbon-based polymer film is thin, active fluorine in the etching gas intrudes into the dielectric film. Moreover, active oxygen in an ashing gas intrudes into the dielectric film at the time of removal of the resist by means of ashing, which is performed after etching.

Gas containing oxygen atoms is usually used in an ashing operation for removing a resist. The Si—R (where R is an alkyl group) bond, the Si—CH₃ bond, or the Si—H bond existing in the dielectric film is broken by active oxygen during the ashing operation, and as a result the Si—OH bond or the Si—O bond may arise. Consequently, an alteration layer, such as SiO₂, is formed within the dielectric film, and this may change the quality of the film. As a result, the dielectric constant of the entire dielectric film is increased, thereby entailing a delay for a signal in an interconnection arising from an increase in wiring capacitance. Thus, the performance of a device is deteriorated.

According to some methods, the substrate is subjected to ashing through use of an oxygen-containing nitrogen gas in order to prevent alteration of the film quality. However, the method fails to inhibit oxidation of a silicon-based film having a low dielectric constant, thereby presenting a problem of a rise in dielectric constant stemming from oxidation.

When gas containing hydrogen atoms is used as an ashing gas, the gas reacts with fluorine still remaining on the low-k film to produce fluoric acid (HF) in some parts of the film. The reactivity of HF is increased by diffusion of fluorine and oxygen, which would be caused by a subsequent film growth process, and wet processing. As a result, reaction defined by Eq. 1 arises.

SiO₂+4HF→SiF₄↑+2H₂O (1)

Here, if the alteration layer, such as SiO₂, is present in the low-k film, the reaction defined by Eq. 1 will proceed. Therefore, the alteration layer is responsible for causing defects or voids in the low-k film. Subsequently, barrier metal or a conductive film is deposited on the low-k film, and is subjected to CMP, thereby removing the barrier metal from the upper surface of the low-k film. At this time, if defects are present in the low-k film, deterioration of a withstand voltage and an electric short-circuit will arise, thereby deteriorating the performance of the device (see, for example, Japanese Laid-Open Patent Publication No. 10-209118).

As mentioned above, the conventional method for ashing a resist on the low-k film usually employs gas containing oxygen atoms. Therefore, the Si—CH₃ bond or the Si—H bond is broken, thereby producing the Si—OH bond or the Si—O bond. Such a change in the quality of the low-k film induces problems, such as an increase in wiring capacitance resulting from a rise in dielectric constant, deterioration of a withstand voltage resulting from defects in the low-k film, and occurrence of an electrical short-circuit.

As a measure against the problems, there may be a case where ashing is carried out through use of a gas mixture containing nitrogen atoms and a smaller quantity of oxygen atoms in the manner described in, e.g., Japanese Laid-Open Patent Publication No. 2001-176859. However, when the substrate having the silicon-based film of low dielectric constant is subjected to ashing, a problem of a rise in dielectric constant still arises, because of oxidation.

Further, as described in, e.g., Japanese Laid-Open Patent Publication No.2002-151479 there may be a case where an attempt is made to inhibit occurrence of a change in the film quality by ashing a resist through application of high-frequency power to the substrate through use of the oxygen-containing gas. This method may shorten a time required for carrying out ashing operation. However, activation of oxygen is enhanced, and hence the surface of the low-k film is oxidized at the time of over-ashing operation, thereby forming a damaged layer. As described in Patent Publication 1, use of a gas mixture consisting of N₂ and H₂ is conceivable, and this may deteriorate a throughput.

### SUMMARY OF THE INVENTION

The invention provides an improved method for manufacturing an electronic device with a view toward solving the problems and inhibiting occurrence of a change in the quality of a film of low dielectric constant, which would otherwise be caused by ashing.

According to one aspect of the present invention, in a method for manufacturing an electronic device, a film of low dielectric constant formed on a substrate is etched while a resist pattern formed on the film of low dielectric constant is taken as a mask. The resist pattern is eliminated by means of ashing through use of ashing gas. Then, an alteration layer which is formed on the film of low dielectric constant and is higher in dielectric constant than the film of low dielectric constant is eliminated.

According to another aspect of the present invention, in a method for manufacturing an electronic device, an oxygen penetration inhibition film is formed for inhibiting penetration of oxygen on the surface or side surfaces of a film of low dielectric constant formed on a substrate. The film of low dielectric constant is etched while the resist pattern formed over the film of low dielectric constant is used as a mask. Then, the resist mask is removed by means of ashing through use of ashing gas.

According to another aspect of the present invention, in a method for manufacturing an electronic device, a film of low dielectric constant formed on a substrate is etched while a resist pattern formed on the film of low dielectric constant is taken as a mask. The resist pattern is eliminated by means of ashing by using as, ashing gas, at least one type of gas or more selected from the group comprising gas containing an alkyl group, gas containing an alkenyl group, gas containing an alkinyl group, and gas containing an aromatic group.

Other and further objects, features and advantages of the invention will appear more fully from the following description.

### BRIEF DESCRIPTION OF THE DRAWINGS

FIG. 1 is a flowchart for describing a method for manufacturing a semiconductor device according to a first embodiment of the invention;

FIGS. 2 through 7 are cross-sectional schematic views for describing the state of each of processes for manufacturing a semiconductor device of the first embodiment of the invention;

FIG. 8 is a flowchart for describing a method for manufacturing a semiconductor device according to a second embodiment of the invention;

FIGS. 9 through 13 are cross-sectional schematic views for describing statuses of respective processes for manufacturing the semiconductor device of the second embodiment of the invention;

FIG. 14 is a flowchart for describing a method for manufacturing a semiconductor device according to a third embodiment of the invention;

FIGS. 15 and 16 are cross-sectional schematic views for describing statuses of respective processes for manufacturing the semiconductor device of the third embodiment of the invention;

FIG. 17 is a flowchart for describing a method for manufacturing a semiconductor device according to a fourth embodiment of the invention;

FIG. 18 is a flowchart for describing a method for manufacturing a semiconductor device according to a fifth embodiment of the invention;

FIG. 19 is a flowchart for describing a method for manufacturing a semiconductor device according to a sixth embodiment of the invention.

### DETAILED DESCRIPTION OF THE PREFERRED EMBODIMENTS

Embodiments of the invention will now be described hereinbelow by reference to the drawings. Throughout the drawings, like or corresponding elements are assigned like reference numerals, and their explanations are simplified or omitted.

First Embodiment

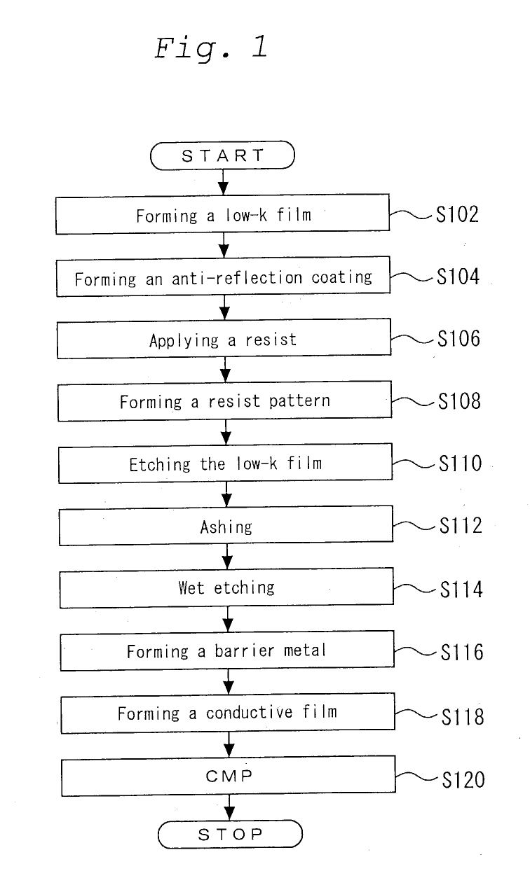

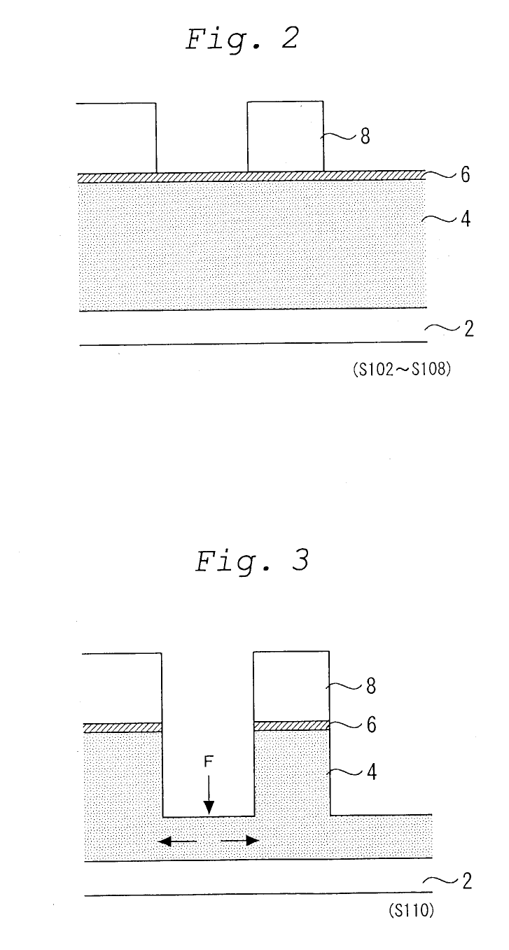

FIG. 1 is a flowchart for describing a method for manufacturing a semiconductor device according to a first embodiment of the invention. FIGS. 2 through 7 are cross-sectional schematic views for describing the state of each of processes for manufacturing a semiconductor device of the first embodiment.

The method for manufacturing an electronic device, such as a semiconductor device, of the first embodiment will now be described by reference to FIGS. 1 through 8.

A film of low dielectric constant 4 (hereinafter called a “low-k film 4”) is formed on a substrate 2 which includes lower structure (step S102). Here, the low-k film 4 is, for example, a dielectric film containing Si, O, and C or a dielectric film containing Si, O, C, and H, such as an organic dielectric film. Here, the dielectric constant “k” is of substantially 3.5 or less. More specifically, the low-k film is formed from, e.g., HSQ (Hydrogen Silsesquioxane), MSQ (Methyl Silsesquioxane), or SiOC.

An anti-reflection coating 6 is formed on the low dielectric constant film 4 (step S104). BARC (Bottom Anti-Reflection Coating), SiON, TiN, or the like is employed as the anti-reflection coating 6. Subsequently, a resist is applied over the surface of the anti-reflection coating 6 (step S106). As shown in FIG. 2, a resist pattern 8 is formed through exposure and development (step S108).

As shown in FIG. 3, the low-k film 4 is etched while the resist pattern 8 is used as a mask (step S110). Here, an F-based gas or a gas mixture containing at least an F-based gas and an O-based gas is used for etching. Such a gas includes, for example, a gas mixture consisting of C₄F₆, CH₂F₂, CO, O₂, and Ar; a gas mixture consisting of C₄F₈, O₂, CO, and Ar; a gas mixture consisting of C₅F₈, O₂, and Ar; or a gas mixture consisting of CHF₃, O₂, and Ar. During the course of etching operation, F-based atoms included in an employed gas intrude into the low-k film.

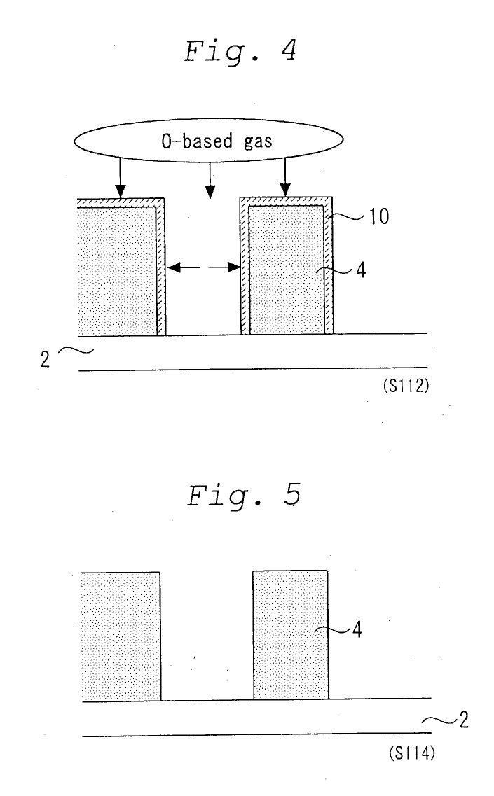

Next, the resist pattern 8 is removed (step S112). Here, when the resist pattern is removed by ashing and when the anti-reflection coating 6 is BARC, the anti-reflection coating 6 is also removed simultaneously. Gas containing oxygen atoms; for example, gas containing O₂, O₃, H₂O, H₂O₂, or N₂O, is used as the ashing gas. During the course of ashing operation, as shown in FIG. 4, the low-k film 4 is altered to a film analogous to SiO₂ by means of active oxygen, whereby an alteration layer 10 is formed.

Next, the substrate is subjected to wet etching (step S114). The wet etching employs a dilute solution of hydrofluoric acid, a solution of ammonium fluoride, or hydrofluoric acid vapors. As shown in FIG. 5, the alteration layer 10 formed on the low-k film 4 is selectively removed by means of wet etching.

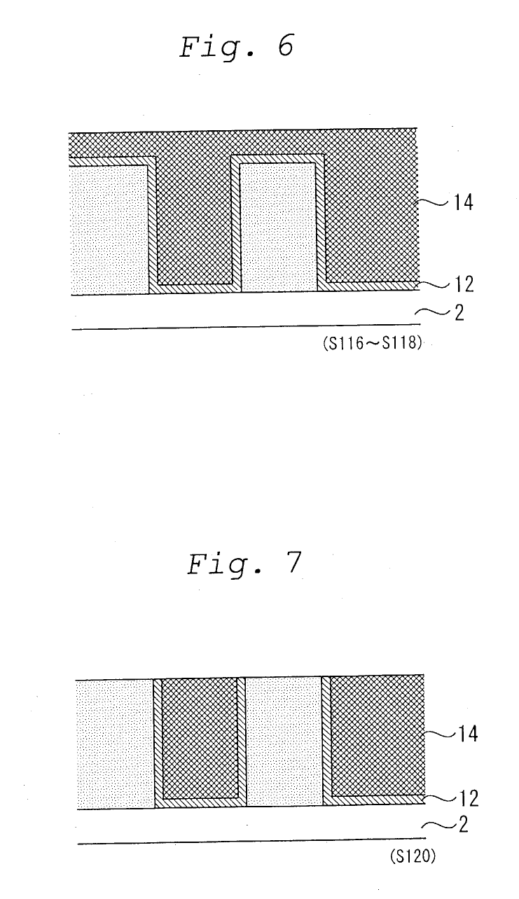

As shown in FIG. 6, a barrier metal film 12 is formed on the low-k film 4 (step S116). Subsequently, a conductive film 14 is deposited on the barrier metal film 12 (step S118). Here, TaN, TiN, or TiW is used as the barrier metal film 12. Further, Cu, Ag, Au, Pt, In, Ti, or W is used as the conductive film 14. Subsequently, the substrate is subjected to smoothing by means of CMP (Chemical-and-Mechanical Polishing) (step S120). As shown in FIG. 7, the conductive film 14 and the barrier metal film 12, both being provided on the low-k film 4, are removed.

As has been described, according to the first embodiment, the alteration layer 10 in which the quality of the low-k film 4 has been altered can be removed by wet etching (step S114). Accordingly, even when an O-based gas is used for ashing the substrate having the silicon-based low-k film 4, a rise in the dielectric film of the overall low-k film 4 can be prevented. As a result, there can be prevented an increase in inter-wiring capacitance, which would otherwise be caused by a rise in dielectric constant, and would otherwise cause occurrence of a delay in signal of a wiring and deterioration of an electrical characteristic of an electronic device, such as a semiconductor device.

The invention is not limited to the materials used for forming the films or the gases employed in the respective processing steps, all being described in connection with the embodiment.

The first embodiment has described a case where a low-k film is formed directly on the substrate 2. However, the invention is not limited to such a case and is effective for ashing a substrate in which a low-k film is formed on another film.

Second Embodiment

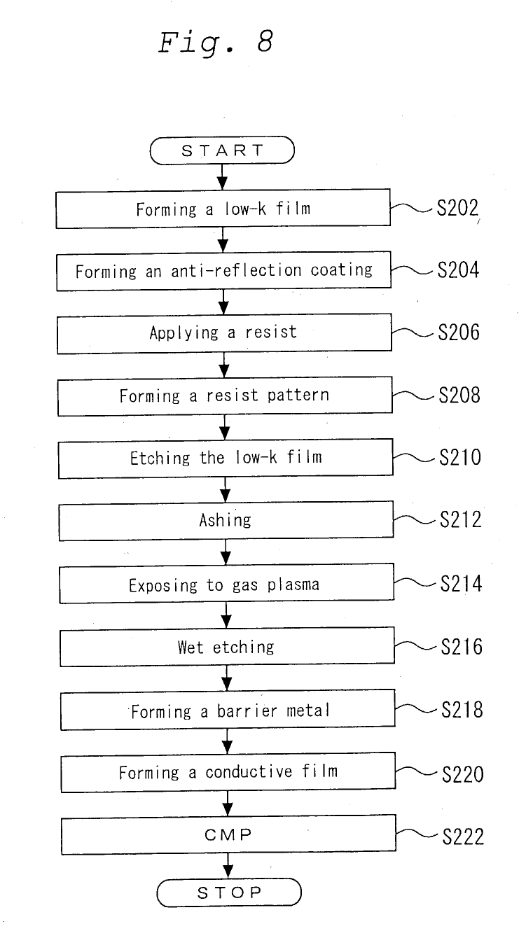

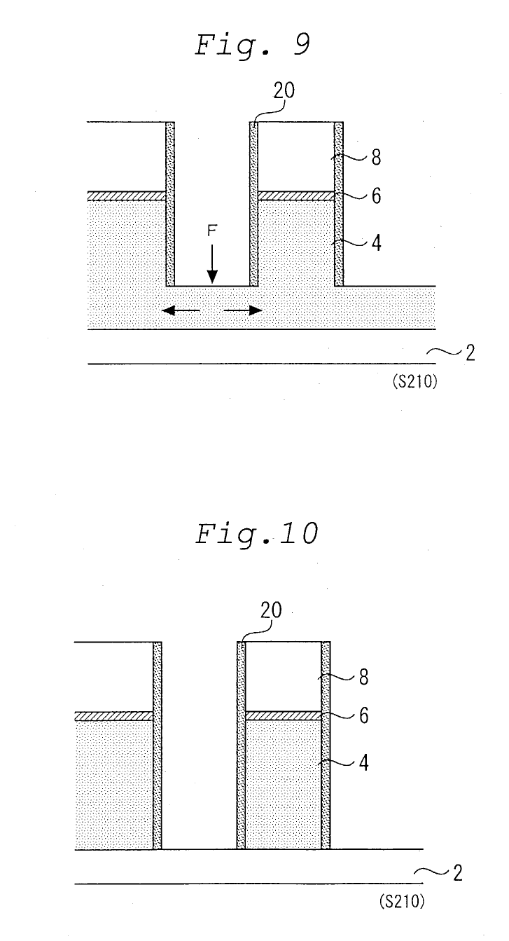

FIG. 8 is a flowchart for describing a method for manufacturing a semiconductor device according to a second embodiment of the invention. FIGS. 9 through 13 are cross-sectional schematic views for describing statuses of respective processes for manufacturing the semiconductor device of the second embodiment.

By reference to FIGS. 8 through 13, a method for manufacturing an electronic device, such as a semiconductor device of the second embodiment will now be described.

As in the case of the first embodiment, the low-k film 4 and the anti-reflection coating 6 are formed on the Substrate 2 (steps S202, S204). The resist pattern 8 is formed also on the anti-reflection coating film 6 (steps S206, S208).

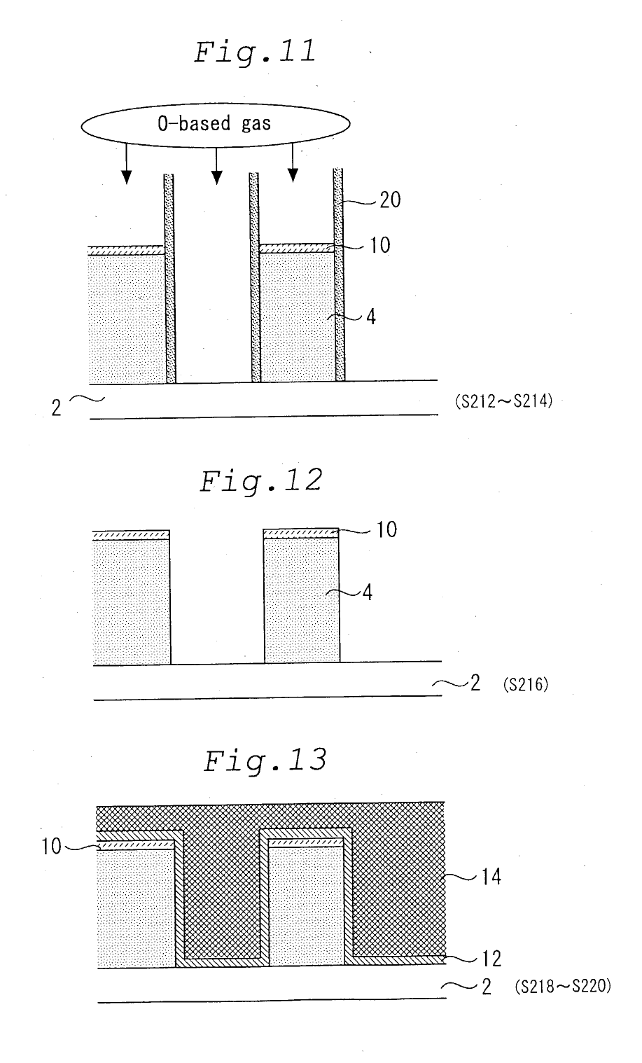

Next, the low-k film 4 is etched while the resist pattern 8 is used as a mask (step S210). Here, a gas mixture containing at least an F-based gas and an O-based gas is used. Further, the proportion of the O-based gas to the entire volume of the gas is adjusted so as to assume a value of 30% or less. As shown in FIG. 9, during the course of etching operation, a pattern is formed on the low-k film 4. Simultaneously, a sturdy fluorocarbon-based polymer film 20 is formed on side walls of the pattern. Since the sturdy fluorocarbon-based polymer film 20 has been simultaneously formed on the side walls of the pattern, intrusion of active fluorine into the low-k film 4 from the side walls can be diminished. As shown in FIG. 10, etching can be completed while the fluorocarbon-based polymer film 20 is formed on the side walls.

As shown in FIG. 11, the resist is removed by ashing. When the anti-reflection coating 6 is formed from BARC, the anti-reflection coating 6 is removed simultaneously (step S212). Here, ashing uses gas containing oxygen atoms. During the ashing operation, the side walls of the pattern of the low-k film 4 are coated with the fluorocarbon-based polymer film 20, thereby preventing intrusion of active oxygen into the low-k film 4 from the side walls. Accordingly, breakage of the Si—CH₃ bond, which would arise in the periphery of the pattern, can be prevented, thereby inhibiting formation of an alteration film such as SiO₂. Since the surface of the low-k film 4 is not coated with the fluorocarbon-based polymer film 20, the alteration film 10 is formed on the surface.

The fluorocarbon-based polymer film 20 is exposed to gas plasma containing an oxygen gas and an F-based gas (S214). If the time during which the polymer film 20 is exposed to the gas plasma becomes longer, active oxygen intrudes into the low-k film 4. Hence, the exposure time is preferably set to a short period of time, such as 10 to 30 seconds or thereabouts. Here, when CF-based polymer adheres to the inside of a reaction processing apparatus, residual F generated from the fluorocarbon-based polymer is utilized. Gas plasma consisting of solely an O-based gas is used as the gas plasma, thereby inhibiting infliction of damage to the low-k film 4.

Subsequently, the substrate is subjected to wet etching (step S216). As a result, as shown in FIG. 12, residues, such as the resist pattern 8 and the anti-reflection coating 6, which have not been eliminated Completely during the ashing process are removed. A solution employed for subjecting the residues to wet etching at this time includes an organic amine-based solution and an ammonium fluoride solution. The fluorocarbon-based polymer film 20 has been exposed to gas plasma beforehand. Thereby, the fluorocarbon-based polymer film 20 can also be eliminated at the time of wet processing.

As shown in FIG. 13, the barrier metal 12 and the conductive film 14 are formed (steps S218, S220). Subsequently, the substrate is subjected to smoothing by CMP (step S222). The alteration layer 10 formed on the surface of the low-k film is also eliminated through CMP.

As has been described, according to the second embodiment, the sturdy fluorocarbon-based polymer film 20 can be formed on the side walls of the low-k film 4 during etching operation. Accordingly, intrusion of active oxygen into the low-k film 4 through the side walls, which would otherwise be caused by ashing, can be prevented. Further, formation of the alteration layer 10 in the vicinity of the sidewalls can also be prevented. Further, the alteration layer 10 is formed on the surface of the low-k film 4. However, the alteration layer 10 on the surface can be readily removed by means of CMP. Accordingly, a rise in the dielectric constant of the entire low-k film 4 is inhibited, and an increase in inter-wiring capacitance, which would otherwise be caused by a rise in dielectric constant, and a delay of a signal in wiring, can also be prevented.

In other respects, the method of the second embodiment is identical with that described in connection with the first embodiment, and hence further explanation is omitted.

Third Embodiment

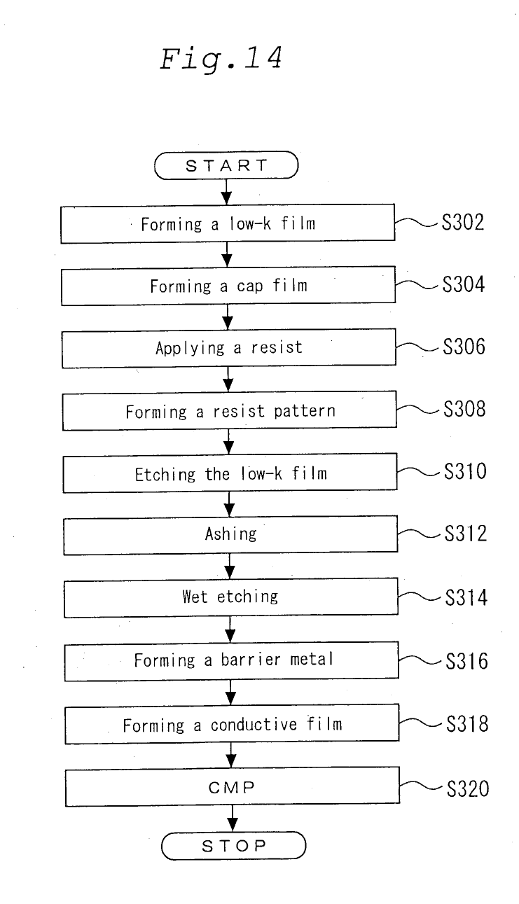

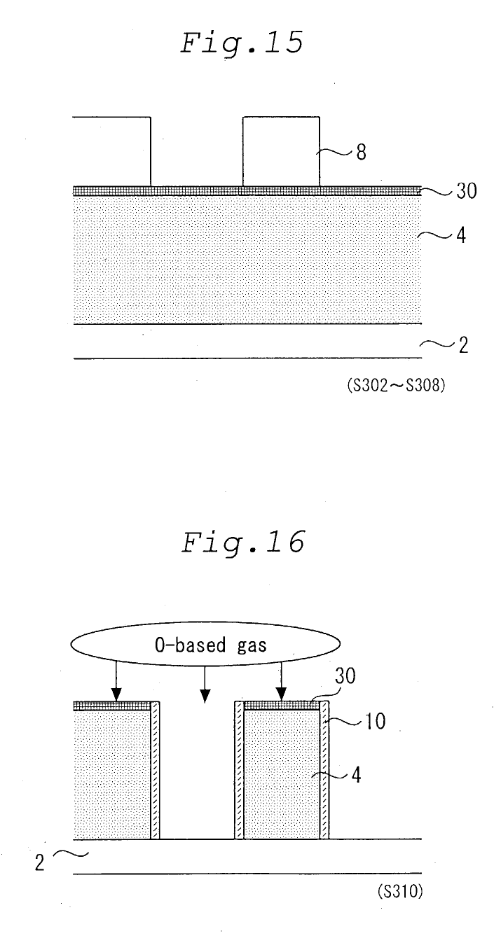

FIG. 14 is a flowchart for describing a method for manufacturing a semiconductor device according to a third embodiment of the invention. FIGS. 15 and 16 are cross-sectional schematic views for describing statuses of respective processes for manufacturing the semiconductor device of the third embodiment.

By reference to FIGS. 14 through 16, a method for manufacturing an electronic device, such as a semiconductor device according to a third embodiment of the invention will now be described.

First, the low-k film 4 is formed on the Substrate 2 (step S302). Subsequently, a cap film 30 is formed (step S304). Here, the cap film 30 is an oxygen penetration prevention film. For instance, SiN or SiON is used for the cap film. Here, the cap film 30 also functions as an anti-reflection coating.

As shown in FIG. 15, the resist pattern 8 is formed on the cap film 30 (steps S306, S308). The low-k film 4 is subjected to etching while the resist pattern 8 is used as a mask (step S310). Here, etching employs an F-based gas or a gas mixture containing at least an F-based gas and an O-based gas.

As shown in FIG. 16, the resist pattern is eliminated (step S312, S314). Gas containing oxygen atoms is used for ashing. Even when the gas containing oxygen atoms is used, the cap film 30 serving as the oxygen permeation prevention film is formed on the surface of the low-k film 4, thereby inhibiting intrusion of oxygen from the surface of the low-k film. Accordingly, generation of an alteration film such as SiO₂, which would otherwise be caused in the vicinity of the surface of the low-k film 4 by means of breakage of the Si—CH₃ bond, can be prevented. Subsequently, the substrate is subjected to wet etching (step S314). Residues still remaining unremoved, such as the resist pattern 8, are removed.

As in the case of the first embodiment, the barrier metal film 12 and the conductive film 14 are formed (steps S316, S318), and the substrate is subjected to smoothing by means of CMP (step S320). During smoothing operation, the cap film 30 is also removed.

As has been described, according to the third embodiment, the cap film 30 serving as an oxygen permeation prevention film is formed on the upper surface of the low-k film 4. Accordingly, intrusion of active oxygen into the low-k film 4 from the surface, which would otherwise arise during etching or ashing, can be prevented. Accordingly, occurrence of a change in the quality of the film located in the vicinity of the low-k film 4 can be inhibited. Therefore, a rise in the dielectric constant of the low-k film can be inhibited. Occurrence of an increase in inter-wiring capacitance and a delay of a signal in wiring can also be prevented.

The third embodiment has described a case where the cap film 30 also functions as the anti-reflection coating. However, the method of the invention is not limited to such a case. An anti-reflection coating, e.g., an organic ARC (BARC), may be provided separately on the cap film 30.

The third embodiment has also described a case where the cap film 30 is formed from SiN, SiON, or the like. However, the invention is not limited to this case. Another film may also be employed, so long as the film can prevented penetration of oxygen.

The third embodiment has also described a case where the cap film 30 is also removed by CMP. The reason for this is that removal of the cap film 30 contributes to a decrease in the dielectric constant of the low-k film 4. However, the invention is not limited to this case. The barrier metal film 12 and the conductive film 14 may be formed while the cap film 30 is left on the surface of the low-k film 4.

The third embodiment has also described a case where the cap film 30 is formed in place of the anti-reflection film and the cap film 30 is left on only the surface of the low-k film 4 after etching. However, the invention is not limited to such a case. After etching, the cap film may be formed on the side walls of the pattern of the low-k film 4, thereby preventing intrusion of oxygen or the like from the side walls of the low-k film 4. Further, the cap film formed on the side walls causes to raise the dielectric constant of the low-k film 4. Hence, removal of the cap film before formation of the barrier metal film 12 is also preferable. When no cap film is formed on the side walls, it is conceivable that the alteration film 10 is formed on the side walls. Therefore, as described in connection with the first embodiment, the alteration film 10 may be removed by wet etching (step S114).

In other respects, the third embodiment is identical with the first and second embodiments, and hence further explanation is omitted.

Fourth Embodiment

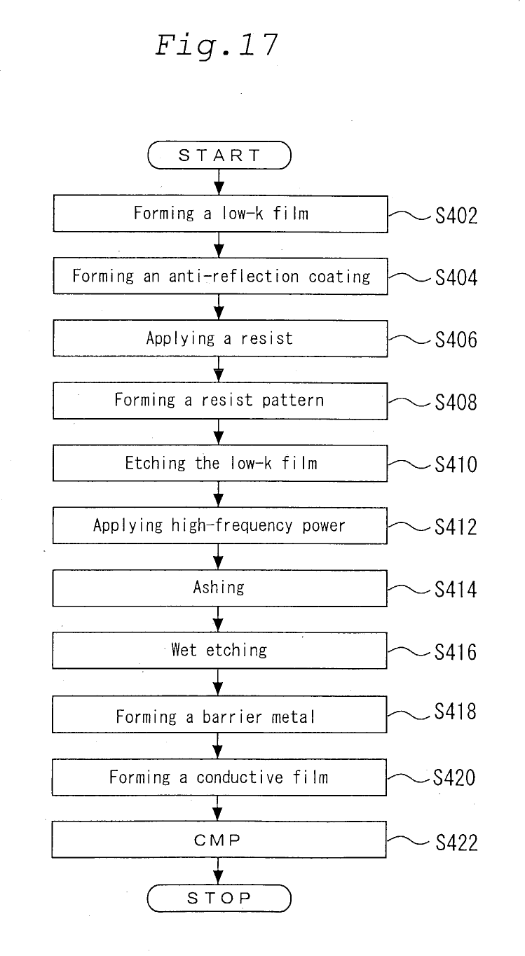

FIG. 17 is a flowchart for describing a method for manufacturing a semiconductor device according to a fourth embodiment of the invention;

The method for manufacturing an electronic device, such as a semiconductor device of the fourth embodiment will now be described by reference to FIG. 17.

As shown in FIG. 2, according to the fourth embodiment, the low-k film 4 and the anti-reflection coating 6 are formed on the Substrate 2 (steps S402, S404). The resist pattern 8 is formed on the anti-reflection coating 6 (steps S406 to S408). Subsequently, the low-k film 4 is etched while the resist pattern 8 is used as a mask (step S410). Here, an F-based gas or a gas mixture containing at least an F-based gas and an O-based gas is used. At this time, active fluorine intrudes into the low-k film 4.

Next, high-frequency power is applied to the inside of the ashing apparatus (step S412). Here, power having a frequency of about 100 kHz or more and a power density of about 0.06 to 3.18 W/cm² or more is applied as the high-frequency power. Ashing is performed while the high-frequency power is being applied to the ashing apparatus (step S414). Here, gas having low oxidation power is used for ashing. In other words, gas having high reduction power; for example, H₂, BCl₃, H₂S, NF₃, NH₃, SiH₄, CH₄, or HCN, is used. After the ashing operation, residues of the resist pattern 8 are removed by wet etching (step S416).

As in the case of the first embodiment, formation of the barrier metal film 12 and the conductive film 14 (steps S418, S420) and smoothing operation involving use of CMP (step S422) are performed.

As has been described, according to the fourth embodiment, gas having high reduction power is used in lieu of the conventional oxygen gas. Accordingly, a change in film quality, which would otherwise be caused by breakage of Si—CH₃ of the low-k film 4, can be inhibited. If reducing gas is used in place of the gas having high oxidizing power, occurrence of a reduction in the throughput is conceivable. However, according to the fourth embodiment, high-frequency power is applied to the ashing apparatus at the time of ashing operation, and hence occurrence of a drop in the throughput, which would otherwise be caused by use of the reducing gas, can be inhibited.

In other respects, the method of the fourth embodiment is identical with those described in connection with the first through third embodiments, and hence further explanation is omitted.

The fourth embodiment has described a case where gas having high reducing power is used at the time of ashing operation. However, the method for manufacturing an electronic device, such as a semiconductor device of the invention may also employ inactive gas such as He, Ne, Ar, Kr, or the like, including chemically-inactive gas such as N₂. A gas mixture containing H₂ and He and a gas mixture of NH₃ and Ar can be used as such an inactive gas. Even in such a case, occurrence of a change in the quality of the low-k film 4, which would otherwise arise during ashing operation, can be inhibited. Even in such a case, occurrence of a drop in throughput can also be inhibited by application of the high-frequency power.

Provision of the process for eliminating an alteration layer so as to follow the ashing process as described in connection with the first embodiment; formation of the fluorocarbon-based polymer film 20 on the side walls of the pattern as described in connection with the second embodiment; or use of the oxygen penetration prevention film 30 (the cap film 30) in place of the anti-reflection coating as described in connection with the third embodiment, may also be used in conjunction with the method of the embodiment. As a result, the quality of the low-k film can be further improved.

Fifth Embodiment

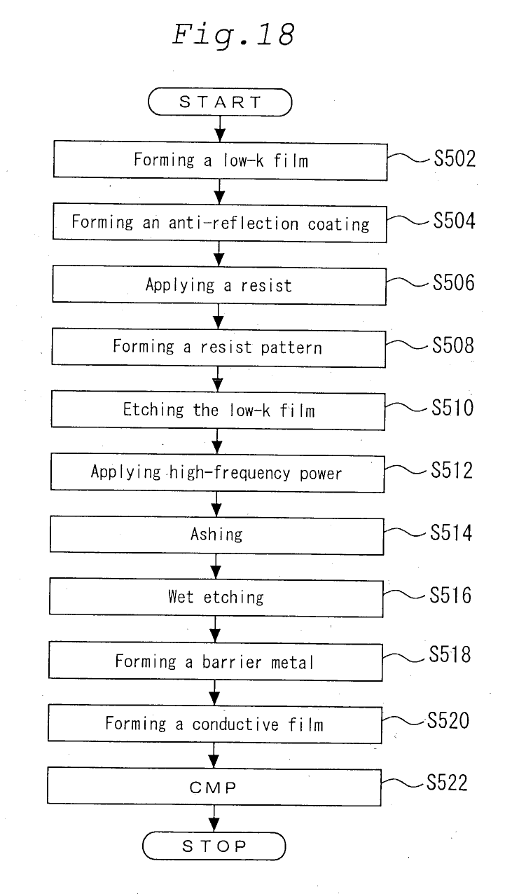

FIG. 18 is a flowchart for describing a method for manufacturing a semiconductor device according to a fifth embodiment of the invention.

The method for manufacturing an electronic device, such as a semiconductor device of the fifth embodiment will now be described by reference to FIG. 18.

As in the case of the first embodiment, the low-k film 4 and the anti-reflection coating 6 are formed on the Substrate 2, and the resist pattern 8 is formed (steps S502 to S508). Subsequently, the low-k film 4 is etched while the resist pattern 8 is used as a mask (step S510). An F-based gas or a gas mixture containing at least an F-based gas and an O-based gas is used as an etching condition. At this time, active fluorine intrudes into the low-k film.

Next, high-frequency power is applied to the ashing apparatus (step S512). Subsequently, the resist pattern 8 is removed by ashing while the high-frequency power is applied to the ashing apparatus (step S514). Here, ashing operation is performed through use of gas capable of supplying a methyl group; for example, a gas containing CH₄, CH₃X (where X denotes halogen), M-CH₃ (where M denotes a metal), CH₃CH₂OH (ethanol), or acetone {(CH₃)₂C═O}. Subsequently, residues of the resist pattern 8, which have not been removed by ashing, are removed by means of wet etching (step S516).

As in the case of the first embodiment, the barrier metal film 12 and the conductive film 14 are formed (steps S518, S520), and the substrate is smoothed by means of CMP (step S522).

As has been described, according to the fifth embodiment, gas capable of supplying a methyl group can be used as ashing gas, thereby inhibiting breakage of the Si—CH₃ bond. For instance, when a component which emits oxygen, such as quartz, is provided in the ashing apparatus, a situation similar to that which would be achieved by use of an O-based gas for ashing can conceivably be created in the ashing apparatus. Accordingly, a change in the quality of the low-k film 4, which would stem from breakage of the SiCH₃ bond, is considered to arise at this time. However, according to the fifth embodiment, gas capable of supplying a methyl group is used during ashing operation, so that revival of the Si—CH₃ bond, which has once been broken, can be promoted. This state is expressed by Eq. 2.

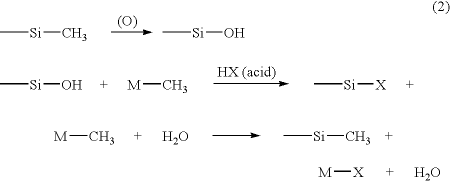

Accordingly, breakage of the Si—CH₃ bond existing in the low-k film 4 is inhibited or the bond can be revived, thereby prevented occurrence of a change in the quality of the low-k film 4.

Here, M denotes a metal; and X denotes a halogen. Further, H₂O which develops in the process must be removed.

The embodiment has described a case where the gas containing a methyl group is used. However, the invention is not limited to such a case. For instance, gas containing an alkyl group (CₓH₂ₓ₊₁), an alkenyl group (including double bonds), an alkinyl group (including triple bonds), or an aromatic group may also be employed. Even when such a gas is used, there can also be yielded an effect of inhibiting breakage of the Si—CH₃ bond or reviving the bond.

Provision of the process for eliminating an alteration layer so as to follow the ashing process as described in connection with the first embodiment; for formation of the fluorocarbon-based polymer film 20 on the sidewalls of the pattern as described in connection with the second embodiment; or for use of the oxygen penetration prevention film 30 in place of the anti-reflection coating as described in connection with the third embodiment, may also be used in conjunction with the method of the fifth embodiment. As a result, the quality of the low-k film can be further improved.

Sixth Embodiment

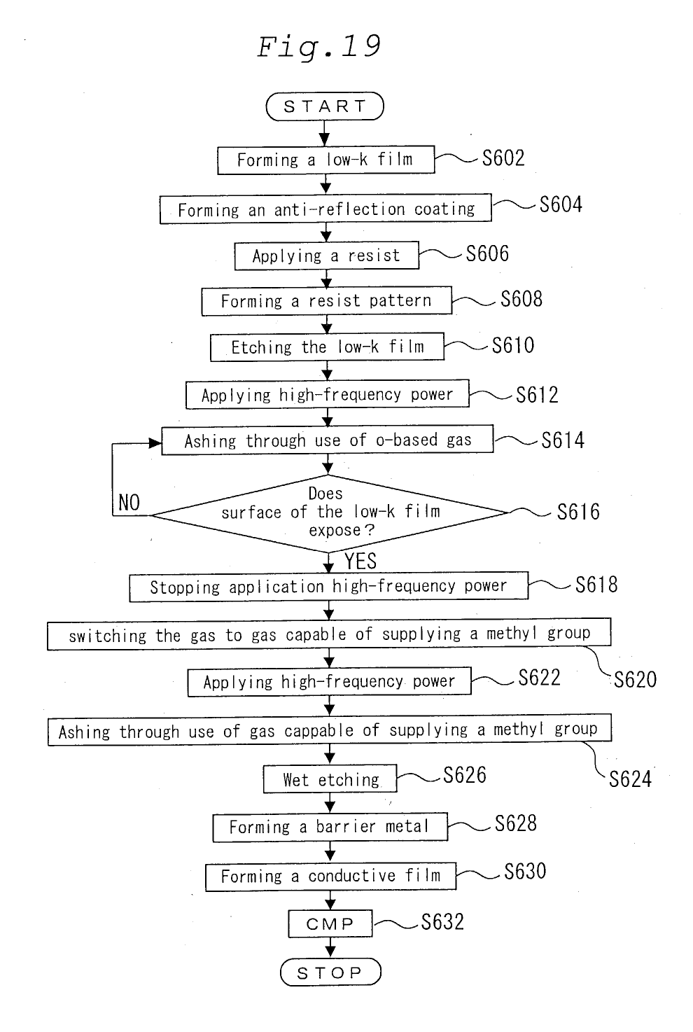

FIG. 19 is a flowchart for describing a method for manufacturing a semiconductor device according to a sixth embodiment of the invention.

The method for manufacturing an electronic device, such as a semiconductor device of the sixth embodiment will now be described by reference to FIG. 19.

As in the case of the first embodiment, the low-k film 4 and the anti-reflection coating 6 are formed on the Substrate 2, and the resist pattern 8 is formed on the anti-reflection coating 6 (steps S602 to S608).

Subsequently, the low-k film is etched while the resist pattern 8 is used as a mask (step S610). An F-based gas or a gas mixture containing at least an F-based gas and an O-based gas is used as an etching condition.

Next, high-frequency power is applied to the ashing apparatus (step S612). Subsequently, the resist pattern is subjected to ashing through use of an O-based gas while the high-frequency power is applied to the ashing apparatus (step S614). During the course of ashing operation, a change in the intensity of emission spectrum of CO or the like is monitored, thereby detecting exposure of the surface of the low-k film 4 (step S616). After exposure of the surface of the low-k film 4, application of the high-frequency power is stopped (step S618). Subsequently, the gas present in the ashing apparatus is switched to gas capable of supplying a methyl group (step S620). The high-frequency power is again applied to the ashing apparatus (step S622). In this state, ashing operation is performed (step S624). Subsequently, residues of the resist pattern 8 are eliminated by means of wet etching (step S626).

Subsequently, formation of the barrier metal film 12 and formation of the conducive film 14 (steps S628, S630) and smoothing of the substrate involving use of CMP (step S632) are performed.

In other respects, the method of the embodiment is identical with that described in connection with the first embodiment, and hence further explanation is omitted.

As has been described, according to the sixth embodiment, ashing operation involving use of the O-based gas is performed until the surface of the low-k film 4 is exposed. Accordingly, the processing time can be shortened further in a stage in which few change arises in the quality of the low-k film 4. As a result, the throughput can be improved. In a state in which the low-k film 4 is not uncovered, active oxygen is consumed by reaction with the resist. Therefore, reaction of active oxygen with the low-k film 4 exposed from the side walls of the pattern can be suppressed to a certain extent.

Even after the gas has been replaced with gas capable of supplying a methyl group, the high-frequency power is still being applied to the ashing apparatus. Consequently, ashing can be performed while a change in the quality of the low-k film 4 is suppressed without involvement of a large drop in throughput. Alternatively, ashing can be performed while revival of the Si—CH₃ bonds, which have once been broken, is promoted.

In other respects, the method of the embodiment is identical with those described in connection with the first through fifth embodiments, and hence further explanation is omitted.

The sixth embodiment has described a case where oxygen gas is switched to gas capable of supplying a methyl group after ashing operation has been performed through use of oxygen gas. However, the invention is not limited to such a case. For instance, as described in connection with the fifth embodiment, breakage of the Si—CH₃ bonds can be suppressed. For instance, as described in connection with the fifth embodiment, gas capable of inhibiting breakage of the Si—CH₃ bonds, such as gas containing an alkyl group (CₓH₂ₓ₊₁), an alkenyl group (including double bonds), an alkinyl group (including triple bonds), or an aromatic group, may also be employed. Alternatively, a reducing gas such as that described in connection with the fourth embodiment or another gas which inhibits occurrence of a change in the quality of the low-k film 4, such as an N-based gas or an H-based gas, may also be employed.

Exposure of the surface of the low-k film 4 is detected by monitoring a change in emission spectrum of CO. However, according to the invention, a method for detecting exposure of the low-k film 4 is not limited to such a method. A method for detecting exposure of the low-k film by monitoring a change in the thickness of a resist pattern may be employed. By means of monitoring a change in the thickness of the resist pattern, ashing gas can be switched from the O-based gas to a gas containing a methyl group before exposure of the surface of the low-k film 4. As a result, a change in the quality of surface of the low-k film 4 can be inhibited.

Provision of the process for eliminating an alteration layer so as to follow the ashing process as described in connection with the first embodiment; for formation of the fluorocarbon-based polymer film 20 on the side walls of the pattern as described in connection with the second embodiment; or for use of the oxygen penetration prevention film 30 in place of the anti-reflection coating as described in connection with the third embodiment, may also be used in conjunction with the method of the embodiment. As a result, the quality of the low-k film can be further improved.

For example, in the first embodiment, processing pertaining to the etching process of the invention is performed by execution of processing pertaining to step S110; processing pertaining to the ashing process of the invention is performed by execution of processing pertaining to step S112; and processing pertaining to the alteration layer elimination process of the invention is performed by execution of processing pertaining to step S114.

Further, in the second embodiment, for example, processing pertaining to the etching process of the invention is performed by execution of processing pertaining to step S210. For instance, in the third embodiment, for example, processing pertaining to the oxygen penetration inhibition film formation process of the invention is performed by execution of processing pertaining to step S304; and processing pertaining to the etching process of the invention is performed by execution of processing pertaining to step S310. For instance, in the second and third embodiments, for example processing pertaining to the ashing processing of the invention is performed by execution of processing pertaining to steps S212, S312.

In the fifth and sixth embodiments, as a result of processing pertaining to steps S512, S622 being performed, processing pertaining to the high-frequency power application process of the invention is performed. Further, processing pertaining to the ashing process is performed by execution of processing pertaining to step S514, S624.

In the sixth embodiment, as a result of, e.g., processing pertaining to step S612 being performed, processing pertaining to the high-frequency power application process is performed; and as a result of processing pertaining to step S614 being performed, processing pertaining to the oxygen ashing process of the invention is performed.

For instance, according to the invention, the oxygen penetration inhibition film means a film capable of inhibiting penetration of oxygen into a film having a low dielectric constant during ashing operation. The oxygen penetration inhibition film corresponds to the fluorocarbon-based polymer film 20 of the second embodiment and the oxygen penetration prevention film 30 of the third embodiment.

The features and the advantages of the present invention as described above may be summarized as follows.

According to one aspect of the present invention, formation of an alteration film, such as SiO₂, can be inhibited, which would otherwise be caused by breakage of the Si—CH₃ bonds during ashing operation. Accordingly, a rise in dielectric constant due to occurrence of a change in the quality of a film having a low dielectric constant can be inhibited, thereby preventing occurrence of an increase in inter-wiring capacitance or a delay of a signal in wiring.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2003-34028, filed on Feb. 12, 2003 including specification, claims, drawings and summary, on which the Convention priority of the present application is based, are incorporated herein by reference in its entirety.

1. A method for manufacturing an electronic device comprising:
an etching step of etching a film of low dielectric constant formed on a substrate while a resist pattern formed on the film of low dielectric constant is taken as a mask;
an ashing step of eliminating the resist pattern by means of ashing through use of ashing gas; and
an alteration layer elimination step of eliminating an alteration layer which is formed on the film of low dielectric constant and is higher in dielectric constant than the film of low dielectric constant.

2. The method for manufacturing an electronic device according to claim 1, wherein the ashing gas contains at least one selected from among inactive gas and reducing gas.

3. The method for manufacturing an electronic device according to claim 1, wherein the ashing gas contains at least one type of atoms among nitrogen atoms and hydrogen atoms.

4. The method for manufacturing an electronic device according to claim 1, wherein the ashing gas is gas containing of at least one member selected from among an alkyl group, an alkenyl group, an alkinyl group, and an aromatic group.

5. The method for manufacturing an electronic device according to claim 1, wherein the film of low dielectric constant assumes a dielectric constant of about 3.5 or less.

6. A method for manufacturing an electronic device comprising:
an oxygen penetration inhibition film formation step of forming an oxygen penetration inhibition film for inhibiting penetration of oxygen on the surface or side surfaces of a film of low dielectric constant formed on a substrate;
an etching step of etching the film of low dielectric constant while the resist pattern formed over the film of low dielectric constant is used as a mask; and
an ashing step of removing the resist mask by means of ashing through use of ashing gas.

7. The method for manufacturing an electronic device according to claim 6, wherein etching gas used in the etching step have a content of 30% or less oxygen is used; and
the etching step and the oxygen penetration inhibition film formation step are carried out at the same time.

8. The method for manufacturing an electronic device according to claim 6, wherein the etching step is carried out after the oxygen penetration inhibition film formation step; and
the oxygen penetration inhibition film is etched in the etching step.

9. The method for manufacturing an electronic device according to claim 8, wherein the oxygen penetration inhibition film is formed from SiN or SiON.

10. The method for manufacturing an electronic device according to claim 6, wherein the ashing gas contains at least one selected from among inactive gas and reducing gas.

11. The method for manufacturing an electronic device according to claim 6, wherein the ashing gas contains at least one type of atoms among nitrogen atoms and hydrogen atoms.

12. The method for manufacturing an electronic device according to claim 6, wherein the ashing gas is gas containing of at least one member selected from among an alkyl group, an alkenyl group, an alkinyl group, and an aromatic group.

13. The method for manufacturing an electronic device according to claim 6, wherein the film of low dielectric constant assumes a dielectric constant of about 3.5 or less.

14. A method for manufacturing an electronic device, comprising:
an etching step of etching a film of low dielectric constant formed on a substrate while a resist pattern formed on the film of low dielectric constant, is taken as a mask; and
an ashing step of eliminating the resist pattern by means of ashing by using as, ashing gas, at least one type of gas or more selected from the group comprising gas containing an alkyl group, gas containing an alkenyl group, gas containing an alkinyl group, and gas containing an aromatic group.

15. The method for manufacturing an electronic device according to claim 14, further comprising an oxygen gas ashing step for performing ashing operation through use of gas containing oxygen gas prior to the ashing step.

16. The method for manufacturing an electronic device according to claim 15, wherein
processing pertaining to the oxygen gas ashing step is performed until a surface of the film of low dielectric constant becomes uncovered; and
processing pertaining to the ashing step is performed after the surface of the film of low dielectric constant has become uncovered.

17. The method for manufacturing an electronic device according to claim 15, wherein
processing pertaining to the oxygen gas ashing step is performed until a surface of the film of low dielectric constant becomes uncovered; and
processing is switched to processing pertaining to the ashing step before the surface of the film of low dielectric constant becomes uncovered.

18. The method for manufacturing an electronic device according to 14, further comprising an high-frequency power application step of applying, after the etching step, high-frequency power to a processing apparatus in which the substrate is stored.

19. The method for manufacturing an electronic device according to claim 14, wherein the film of low dielectric constant assumes a dielectric constant of about 3.5 or less.
